(19) United States
(12) Patent Application Publication
(10) Pub. No.: US 2025/0293124 A1
(43) Pub. Date: Sep. 18, 2025

(54) SEMICONDUCTOR DEVICE AND METHOD FOR MANUFACTURING THE SAME

(71) Applicant: Rohm Co., Ltd., Kyoto-shi (JP)

(72) Inventor: Naoyuki SANO, Kyoto-shi (JP)

(21) Appl. No.: 19/076,393

(22) Filed: Mar. 11, 2025

(30) Foreign Application Priority Data
Mar. 14, 2024 (JP) 2024-040361

(51) Int. Cl. H01L 23/495; H01L 23/06

(52) U.S. Cl. CPC H01L 23/4952; H01L 23/06; H01L 23/49551

(57) ABSTRACT

A semiconductor device includes a conductive member, a semiconductor element, and a sealing resin. The conductive member includes a wiring portion having first and second main surfaces respectively facing first and second sides in a thickness direction, and a terminal portion being connected to the wiring portion from the second side and having a third main surface facing the second side. The semiconductor element is on the second side with respect to the wiring portion, is bonded to the second main surface, and has first and second element main surfaces. The wiring portion has a first side surface facing orthogonal to the thickness direction. The terminal portion has a second side surface facing orthogonal to the thickness direction and connected to the first side surface. The second element main surface and at least one of the first and second side surfaces are exposed from the sealing resin.

### FIELD

The present disclosure relates to a semiconductor device and a method for manufacturing a semiconductor device.

### BACKGROUND

Various configurations have been proposed for semiconductor devices with semiconductor elements. An example of a conventional semiconductor device is disclosed in JP-A-2020-77694. The semiconductor device disclosed in the document includes a lead, a semiconductor element, and a sealing resin. In the semiconductor device disclosed in the document, the semiconductor element is mounted on the lead by flip-chip mounting. The lead has an obverse surface facing one side in the thickness direction and a reverse surface facing the other side in the thickness direction. The semiconductor element is disposed to face the obverse surface of the lead and bonded to the obverse surface of the lead via a bonding layer made of solder, for example. The sealing resin covers the entirety of the semiconductor element and a portion of the lead. The reverse surface of the lead is exposed from the sealing resin and bonded to a circuit board via a bonding material, for example.

In the semiconductor device having the above configuration, the heat generated in the semiconductor element is dissipated through the bonding layer and the lead. However, as the amount of heat generated in the semiconductor element increases with an increased current of the semiconductor device, there is a concern that the heat dissipation via the lead may become insufficient.

### DRAWINGS

FIG. 1 is a plan view of a semiconductor device according to a first embodiment of the present disclosure.

FIG. 2 is a plan view of the semiconductor device (as seen through an insulating layer) according to the first embodiment of the present disclosure.

FIG. 3 is a plan view of the semiconductor device (as seen through the insulating layer and a sealing resin) according to the first embodiment of the present disclosure.

FIG. 4 is a bottom view of the semiconductor device according to the first embodiment of the present disclosure.

FIG. 5 is a front view of the semiconductor device according to the first embodiment of the present disclosure.

FIG. 6 is a sectional view taken along line VI-VI in FIG. 3.

FIG. 7 is a sectional view taken along line VII-VII in FIG. 3.

FIG. 8 is a sectional view showing a step of a manufacturing method of the semiconductor device according to the first embodiment of the present disclosure.

FIG. 9 is a sectional view showing the step subsequent to the step of FIG. 8.

FIG. 10 is a sectional view showing the step subsequent to the step of FIG. 9.

FIG. 11 is a sectional view showing the step subsequent to the step of FIG. 10.

FIG. 12 is a sectional view showing the step subsequent to the step of FIG. 11.

FIG. 13 is a sectional view showing the step subsequent to the step of FIG. 12.

FIG. 14 is a sectional view showing the step subsequent to the step of FIG. 13.

FIG. 15 is a sectional view showing the step subsequent to the step of FIG. 14.

FIG. 16 is a sectional view showing an example of the use of the semiconductor device according to the first embodiment of the present disclosure.

FIG. 17 is a sectional view corresponding to FIG. 6, showing a semiconductor device according to a first variation of the first embodiment.

FIG. 18 is a sectional view corresponding to FIG. 6, showing a semiconductor device according to a second variation of the first embodiment.

FIG. 19 is a sectional view showing a step of a manufacturing method of the semiconductor device according to the second variation of the first embodiment.

FIG. 20 is a sectional view showing the step subsequent to the step of FIG. 19.

FIG. 21 is a sectional view showing the step subsequent to the step of FIG. 20.

FIG. 22 is a sectional view corresponding to FIG. 6, showing a semiconductor device according to a second embodiment of the present disclosure.

FIG. 23 is a sectional view showing a step of a manufacturing method of the semiconductor device according to the second embodiment of the present disclosure.

FIG. 24 is a sectional view showing the step subsequent to the step of FIG. 23.

FIG. 25 is a sectional view showing the step subsequent to the step of FIG. 24.

FIG. 26 is a sectional view showing the step subsequent to the step of FIG. 25.

FIG. 27 is a sectional view showing the step subsequent to the step of FIG. 26.

FIG. 28 is a sectional view showing the step subsequent to the step of FIG. 27.

FIG. 29 is a sectional view showing the step subsequent to the step of FIG. 28.

FIG. 30 is a sectional view showing the step subsequent to the step of FIG. 29.

FIG. 31 is a sectional view showing the step subsequent to the step of FIG. 30.

### EMBODIMENTS

The following describes preferred embodiments of the present disclosure in detail with reference to the drawings.

Hereinafter, the elements that are identical or similar are denoted by the same reference signs, and the descriptions thereof are omitted. In the present disclosure, the terms such as “first”, “second”, and “third” are used merely as labels and are not intended to impose ordinal requirements on the items to which these terms refer.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”. In addition, the expression “An object A (or its material) contains a certain material C” includes the situation where “the object A (or its material) is made of the material C” and the situation where “the main component of the object A (or its material) is the material C”. Furthermore, in the description of the present disclosure, the expression “A surface A faces (a first side or a second side) in a direction B” is not limited to the situation where the angle of the surface A to the direction B is 90° and includes the situation where the surface A is inclined with respect to the direction B.

### First Embodiment

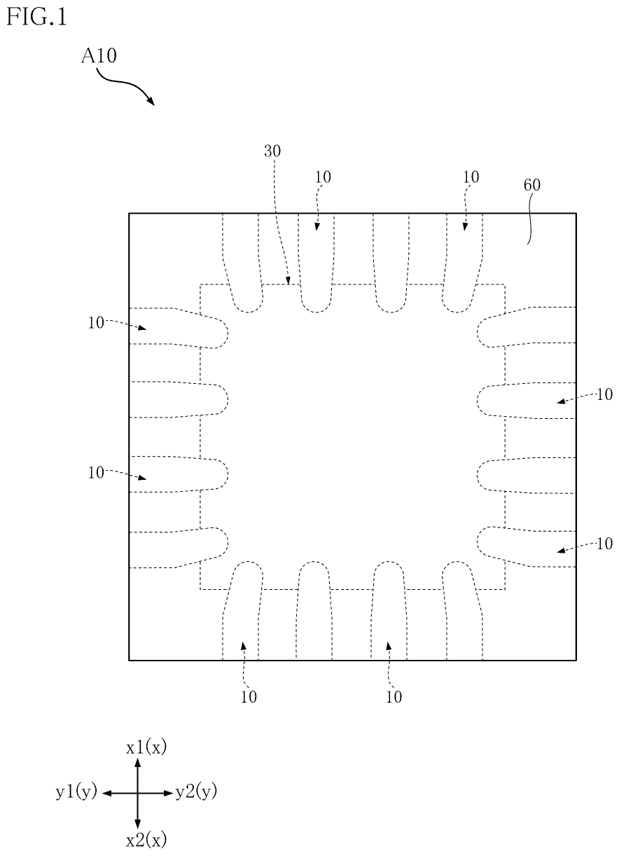

A semiconductor device according to a first embodiment of the present disclosure will be described based on FIGS. 1 to 7. The semiconductor device A10 of the present embodiment includes a plurality of conductive members 10, a semiconductor element 30, and a scaling resin 40. In the present embodiment, the semiconductor device A10 further includes bonding layers 39, first metal layers 51, a seed layer 52, a second metal layer 53, and an insulating layer 60. As shown in FIGS. 1 to 5, the package type for semiconductor device A10 is the QFN (Quad For Non-Lead Package). The package type of the semiconductor device A10 is not limited to the QFN.

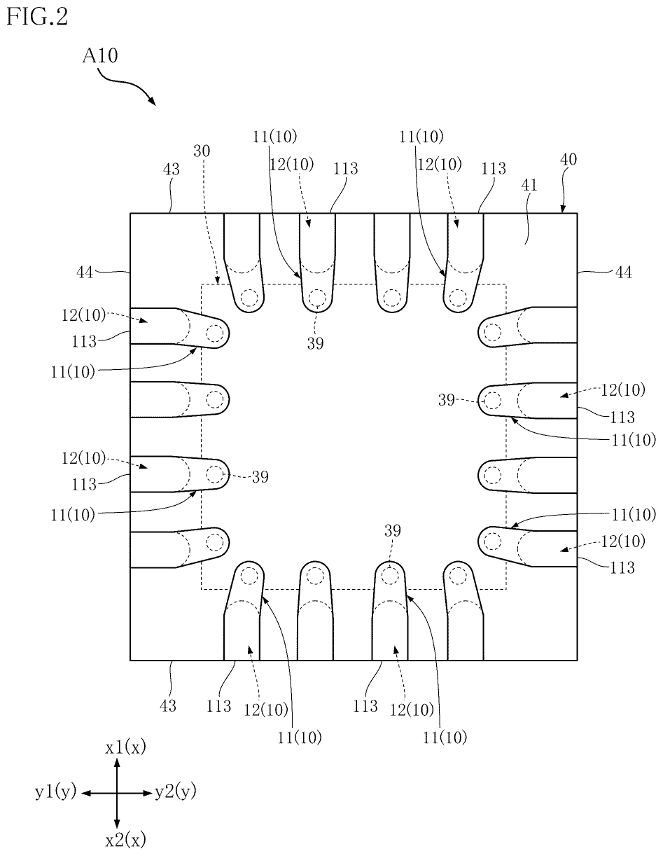

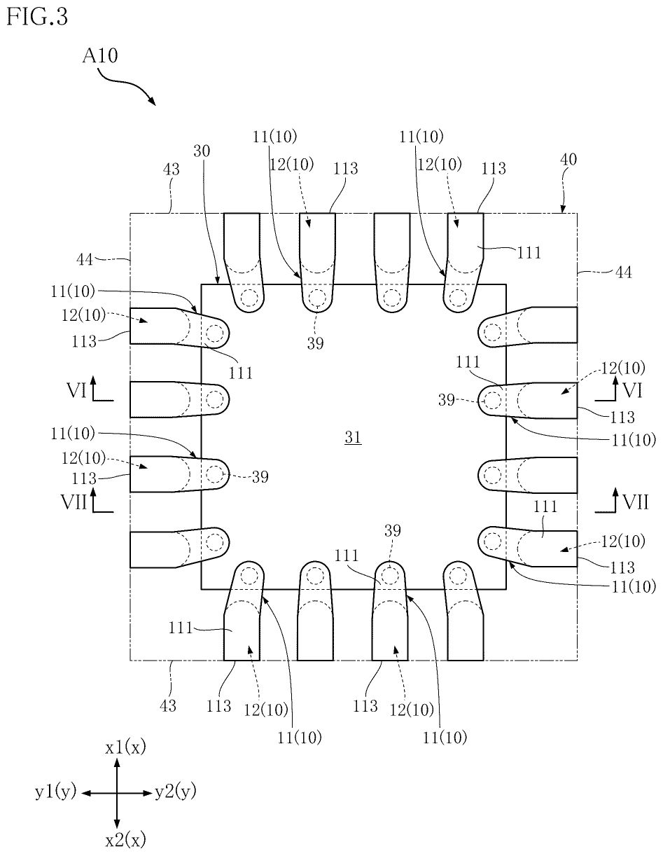

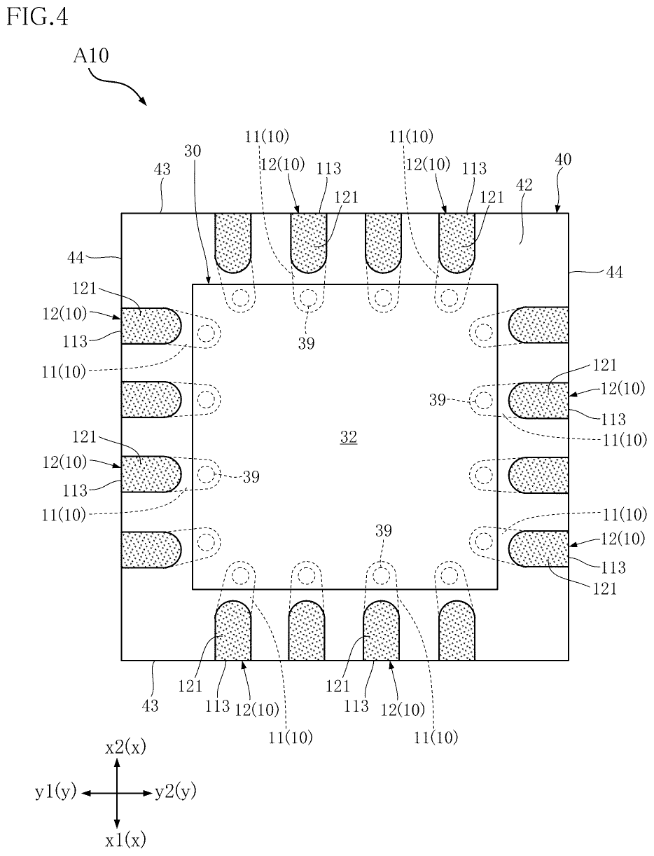

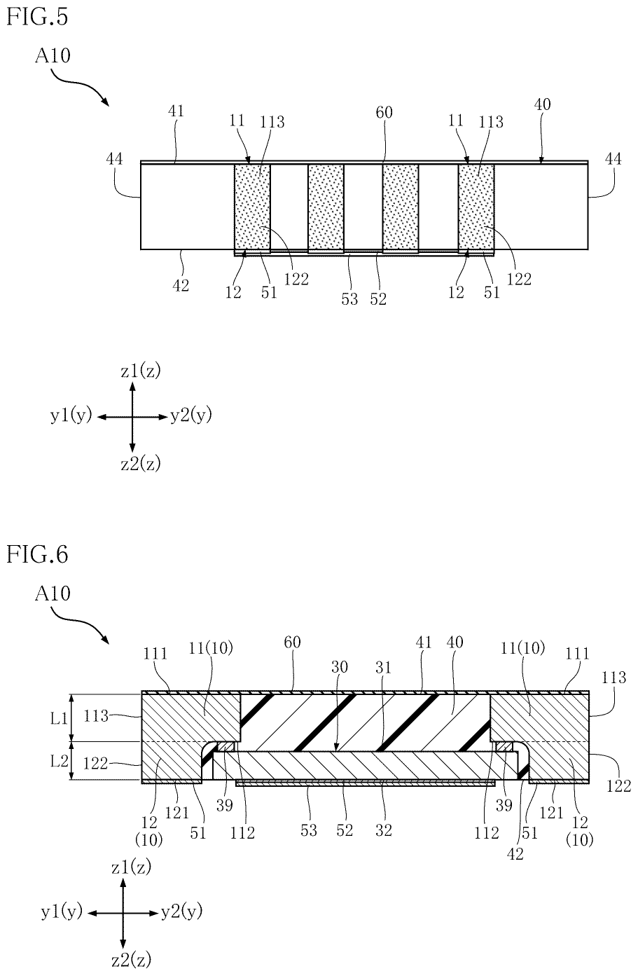

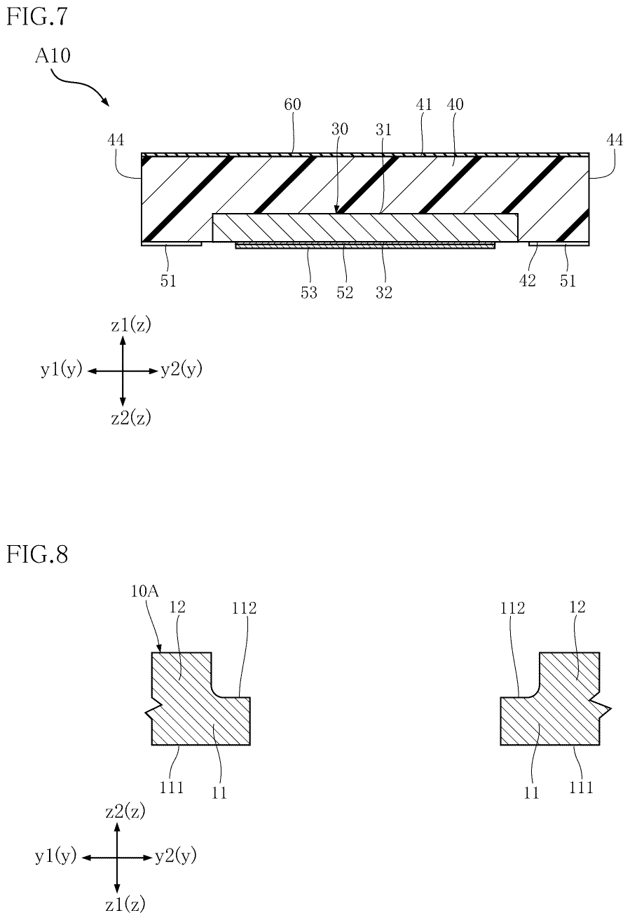

FIG. 1 is a plan view of the semiconductor device A10. FIG. 2 is a plan view of the semiconductor device A10 as seen through the insulating layer 60. FIG. 3 is a plan view of the semiconductor device A10 as seen through the insulating layer 60 and the sealing resin 40. FIG. 4 is a bottom view of the semiconductor device A10. In FIG. 4, the first metal layers 51, the seed layer 52, and the second metal layer 53 are omitted. FIG. 5 is a front view of the semiconductor device A10. FIG. 6 is a sectional view taken along line VI-VI in FIG. 3. FIG. 7 is a sectional view taken along line VII-VII in FIG. 3. Incidentally, the outline of the sealing resin 40 is indicated by imaginary line (two-dot chain line) in FIG. 3.

In the description of the semiconductor device A10, the thickness direction (the plan-view direction) of the semiconductor device A10 is defined as the “thickness direction z”. A direction orthogonal to the thickness direction z is defined as the “first direction x”. The direction orthogonal to the thickness direction z and the first direction x is defined as the “second direction y”. As shown in FIGS. 1 and 2, the semiconductor device A10 is rectangular as viewed in the thickness direction z. In the description of the semiconductor device A10, one side in the first direction x is defined as the “x1 side in the first direction x”, and the other side in the first direction x is defined as the “x2 side in the first direction x”. Further, one side in the second direction y is defined as the “y1 side in the second direction y”, and the other side in the second direction y is defined as the “y2 side in the second direction y”. Still further, one side in the thickness direction z is defined as the “z1 side in the thickness direction z”, and the other side in the thickness direction z is defined as the “z2 side in the thickness direction z”.

As shown in FIGS. 2 to 7, the sealing resin 40 covers a portion of each conductive member and a portion of the semiconductor element 30. The sealing resin 40 has electrical insulation properties. Examples of the material of the sealing resin 40 include a black epoxy resin. The scaling resin 40 is rectangular as viewed in the thickness direction z.

The sealing resin 40 has a first resin main surface 41, a second resin main surface 42, a pair of resin side surfaces 43, and a pair of resin side surfaces 44. The first resin main surface 41 and the second resin main surface 42 face away from each other in the thickness direction z. The first resin main surface 41 faces the z1 side in the thickness direction z. The second resin main surface 42 faces the z2 side in the thickness direction z. The pair of resin side surfaces 43 are connected to both the first resin main surface 41 and the second resin main surface 42 and face away from each other in the first direction x. One of the resin side surfaces 43 faces the x1 side in the first direction x, and the other resin side surface 43 faces the x2 side in the first direction x. The resin side surfaces 43 are spaced apart from each other in the first direction x. The pair of resin side surfaces 44 are connected to both the first resin main surface 41 and the second resin main surface 42 and face away from each other in the second direction y. One of the resin side surfaces 44 faces the y1 side in the second direction y, and the other resin side surface 44 faces the y2 side in the second direction y. The resin side surfaces 44 are spaced apart from each other in the second direction y.

As shown in FIGS. 3, 4, and 6, the plurality of conductive members 10 have the semiconductor element 30 mounted thereon. The conductive members 10, for example, form a conductive path between the semiconductor element 30 and the circuit board or the like on which the semiconductor device A10 is mounted. As shown in FIGS. 1 to 6, the conductive members 10 are disposed at intervals along the periphery of the rectangular sealing resin 40 as viewed in the thickness direction z. In the illustrated example, four conductive members 10 are disposed at intervals in the second direction y along each of the resin side surfaces 43 on opposite sides in the first direction x of of the sealing resin 40. Also, four conductive members 10 are disposed at intervals in the first direction x along each of the resin side surfaces 44 on opposite sides in the second direction y of the sealing resin 40. The arrangement of the conductive members 10 is not limited to the illustrated example.

As shown in FIG. 6, each conductive member 10 is partially covered with the sealing resin 40. Each conductive member 10 includes a wiring portion 11 and a terminal portion 12. The wiring portions 11 of the conductive members 10 are located at the same position in the thickness direction z. The wiring portion 11 of each conductive member 10 extends inwardly from the periphery (one of the resin side surfaces 43 and 44) of the scaling resin 40 as viewed in the thickness direction z.

Each wiring portion 11 has a first main surface 111, a second main surface 112, and a first side surface 113. The first main surface 111 and the second main surface 112 face away from each other in the thickness direction z. The first main surface 111 faces the z1 side in the thickness direction z. The first main surface 111 is exposed from the first resin main surface 41 of the sealing resin 40. The second main surface 112 faces the z2 side in the thickness direction z and faces the semiconductor element 30. The semiconductor element 30 is mounted on the second main surface 112. The second main surface 112 is covered with the scaling resin 40.

The first side surface 113 faces in a direction orthogonal to the thickness direction z. The first side surface 113 faces one of the x1 side in the first direction x, the x2 side in the first direction x, the y1 side in the second direction y, and the y2 side in the second direction y. In the illustrated example, the first side surface 113 of each of the conductive members 10 disposed along the resin side surface 43 facing the x1 side in the first direction x of the sealing resin 40 faces the x1 side in the first direction x. The first side surface 113 of each of the conductive members 10 disposed along the resin side surface 43 facing the x2 side in the first direction x of the sealing resin 40 faces the x2 side in the first direction x. The first side surface 113 of each of the conductive members disposed along the resin side surface 44 facing the y1 side in the second direction y of the scaling resin 40 faces the y1 side in the second direction y. The first side surface 113 of each of the conductive members 10 disposed along the resin side surface 44 facing the y2 side in the second direction y of the sealing resin 40 faces the y2 side in the second direction y. As shown in FIGS. and 6, the first side surfaces 113 are exposed from the sealing resin 40 (the resin side surfaces 43 or the resin side surfaces 44). Each first side surface 113 is flush with a corresponding one of the resin side surfaces 43 and 44.

Each terminal portion 12 is connected to a wiring portion 11 on the z2 side in the thickness direction z. In each of the conductive members 10, the terminal portion 12 is located at the periphery of the sealing resin 40 as viewed in the thickness direction z.

Each terminal portion 12 has a third main surface 121 and a second side surface 122. The third main surface 121 faces the z2 side in the thickness direction z. The third main surface 121 is exposed from the second resin main surface 42 of the sealing resin 40. The third main surface 121 is flush with the second resin main surface 42. The surface roughness of the third main surface 121 is greater than that of the first main surface 111.

The second side surface 122 faces in a direction orthogonal to the thickness direction z. The second side surface 122 faces one of the x1 side in the first direction x, the x2 side in the first direction x, the y1 side in the second direction y, and the y2 side in the second direction y. In the illustrated example, the second side surface 122 of each of the conductive members 10 disposed along the resin side surface 43 facing the x1 side in the first direction x of the sealing resin 40 faces the x1 side in the first direction x. The second side surface 122 of each of the conductive members disposed along the resin side surface 43 facing the x2 side in the first direction x of the sealing resin 40 faces the x2 side in the first direction x. The second side surface 122 of each of the conductive members 10 disposed along the resin side surface 44 facing the y1 side in the second direction y of the sealing resin 40 faces the y1 side in the second direction y. The second side surface 122 of each of the conductive members 10 disposed along the resin side surface 44 facing the y2 side in the second direction y of the sealing resin 40 faces the y2 side in the second direction y. As shown in FIGS. 5 and 6, the second side surfaces 122 are connected to the first side surfaces 113 and exposed from the scaling resin 40 (the resin side surfaces 43 or the resin side surfaces 44). The second side surfaces 122 are flush with the first side surfaces 113. Further, each second side surface 122 is flush with a corresponding one of the resin side surfaces 43 and 44.

The constituent material of the conductive members 10 includes copper (Cu), for example. The conductive members 10 are, for example, leads, and can be obtained from the same lead frame. The configuration of the conductive members 10 that includes the second main surface 112 (the wiring portion 11) recessed from the third main surface 121 to the z1 side in the thickness direction z is formed by removing a part corresponding to the wiring portion 11 from the third main surface 121 of the conductive member 10 (the terminal portion 12) by half etching. As shown in FIG. 6, the half etching forms a rounded shape at the boundary between the second main surface 112 of the wiring portion 11 and the terminal portion 12 connected to it.

As an example of the dimensions in the thickness direction z of the wiring portion 11 and the terminal portion 12, the first dimension L1 in the thickness direction z of the wiring portion 11 is approximately equal to or greater than 50 μm and equal to or less than 100 μm, and preferably, approximately equal to or greater than 75 μm and equal to or less than 100 μm. The second dimension L2 in the thickness direction z of the terminal portion 12 is approximately equal to or greater than 65 μm and equal to or less than 140 μm, and preferably, approximately equal to or greater than 65 μm and equal to or less than 90 μm. For example, the first dimension L1 in the thickness direction z of the wiring portion 11 is equal to or greater than 35% and equal to or less than 150% of the second dimension L2 in the thickness direction z of the terminal portion 12. Preferably, the first dimension L1 is equal to or greater than 115% and equal to or less than 150% of the second dimension L2, and the first dimension L1 is greater than the second dimension L2. In the illustrated example, the first dimension L1 in the thickness direction z of the wiring portion 11 is approximately 100 μm, and the second dimension L2 in the thickness direction z of the terminal portion 12 is approximately 80 μm.

The semiconductor element 30 is an element that performs the main electrical functions in the semiconductor device A10. The specific examples of the semiconductor elements 30 are not limited in any way, and include, for example, an LSI (Large Scale Integration) and an IC (Integrated Circuit). The specific shape and size of the semiconductor element 30 are not limited in any way. In present embodiment, for example, semiconductor element 30 is rectangular as viewed in the thickness direction z. As shown in FIG. 6, the semiconductor element 30 has a first element main surface 31 and a second element main surface 32. The first element main surface 31 faces the z1 side in the thickness direction z. The first element main surface 31 faces the second main surfaces 112 of the wiring portions 11. The first element main surface 31 is covered with the sealing resin 40. The second element main surface 32 faces the z2 side in the thickness direction z. The second element main surface 32 is exposed from the second resin main surface 42 of the scaling resin 40. The second element main surface 32 is flush with the second resin main surface 42.

As shown in FIG. 6, the semiconductor element 30 is electrically connected to the conductive members 10 (the wiring portions 11) by flip chip bonding. Specifically, a plurality of electrode pads (not shown) are provided on the first element main surface 31. The semiconductor element 30 (the electrode pads) electrically conducts to at least one of the wiring portions 11 via a bonding layer 39. The bonding layer 39 is disposed between the second main surface 112 and the first element main surface 31 (the electrode pad) and in contact with both the second main surface 112 and the first element main surface 31 (the electrode pad). The bonding layer 39 is electrically conductive. Thus, the semiconductor element 30 (the electrode pads) is conductively bonded to the second main surfaces 112 of the conductive members 10 (the wiring portions 11). The bonding layer 39 is, for example, solder (a metal containing tin and silver).

As described above, the terminal portions 12 of the conductive members 10 are located at the periphery of the rectangular sealing resin 40 as viewed in the thickness direction z. As shown in FIGS. 2 to 4 and 6, the terminal portions 12 of the conductive members 10 surround the semiconductor element 30 as viewed in the thickness direction z. The semiconductor element 30 is located on the z2 side (the same side as the terminal portions 12) in the thickness direction z with respect to the wiring portions 11, and each terminal portion 12 overlaps with the semiconductor element 30 as viewed in a direction orthogonal to the thickness direction z. As an example of the dimensions of the semiconductor element 30, the dimension in the thickness direction z of the semiconductor element is approximately equal to or greater than 25 μm and equal to or less than 50 μm.

As shown in FIGS. 5 and 6, the first metal layers 51 are located on the z2 side in the thickness direction z with respect to the third main surfaces 121 of the terminal portions 12. The first metal layers 51 are in contact with the third main surfaces 121. The first metal layers 51 are, for example, plating layers formed on the third main surfaces 121. The first metal layers 51 are not limited to a particular material, but may be, nickel (Ni), palladium (Pd), and gold (Au) plating layers deposited in this order.

The seed layer 52 is located on the z2 side in the thickness direction z with respect to the second element main surface 32 of the semiconductor element 30. The seed layer 52 is in contact with the second element main surface 32. The seed layer 52 is a thin film layer consisting of, for example, a titanium (Ti) layer and a copper (Cu) layer deposited on top of each other. The seed layer 52 covers most of the second element main surface 32.

The second metal layer 53 is located on the z2 side in the thickness direction with respect to the second element main surface 32 of the semiconductor element 30. The seed layer 52 is located between the second element main surface 32 and the second metal layer 53. The second metal layer 53 is in contact with the seed layer 52. The second metal layer 53 is a plating layer formed on the seed layer 52. The second metal layer 53 is not limited to a particular material, but may be, nickel (Ni), palladium (Pd), and gold (Au) plating layers deposited in this order. In the present embodiment, the second metal layer 53 is made of the same material as the first metal layer 51. Unlike the present embodiment, the semiconductor device of the present disclosure may not include the first metal layers 51, the seed layer 52, and the second metal layer 53.

The insulating layer 60 is located on the z1 side in the thickness direction z with respect the first main surfaces 111 of the wiring portions 11. The insulating layer 60 is in contact with the first main surface 111. In the present embodiment, the insulating layer 60 is in contact with and covers the entirety of the first main surfaces 111 of the wiring portions 11 (the conductive members 10) and the first resin main surface 41. The structure of the insulating layer 60 is not particularly limited, and may be a ceramic sheet or an insulating resin sheet, for example. Unlike the present embodiment, the semiconductor device of the present disclosure may not include the insulating layer 60.

Next, an example of a method for manufacturing the semiconductor device A10 will be described with reference to FIGS. 8 to 15. FIGS. 8 to 15 are sectional views corresponding to FIG. 6, each showing a step of the manufacturing method of the semiconductor device A10. In FIGS. 8 to 15, the z1 side and the z2 side in the thickness direction z are inverted.

First, a conductive member 10A is prepared as shown in FIG. 8. The conductive member 10A is formed from a lead frame. The conductive member 10A has a size that allows production of a plurality of semiconductor devices A10 described above. That is, the manufacturing steps described below are the steps of a method for manufacturing a plurality of semiconductor devices A10 collectively.

The conductive member 10A includes wiring portions 11 and terminal portions 12. Each wiring portion 11 has a first main surface 111 facing the z1 side in the thickness direction z and a second main surface 112 facing the z2 side in the thickness direction z. The terminal portion 12 is connected to the z2 side in the thickness direction z of the wiring portion 11. Such a configuration including the second main surface 112 (the wiring portion 11) recessed to the z1 side in the thickness direction z is formed by removing a part of the wiring portion 11 from the z2 side in the thickness direction z of the conductive member 10 by half etching.

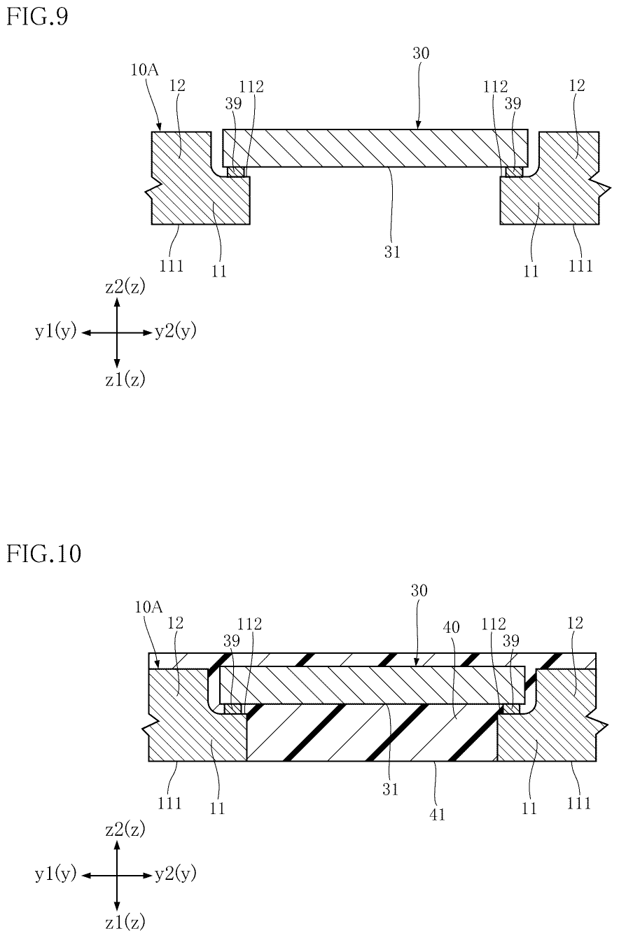

Next, the semiconductor element 30 is placed on the second main surfaces 112 of the wiring portions 11, as shown in FIG. 9. Specifically, the semiconductor element 30 is placed on the second main surfaces 112 via bonding layers 39. The bonding layers 39 are, for example, solder. By carrying out a heating process (reflow process) after the semiconductor element 30 is placed, the materials of the bonding layers 39 melt, and the semiconductor element 30 and the second main surfaces 112 (the wiring portions 11) are conductively bonded via the bonding layers 39.

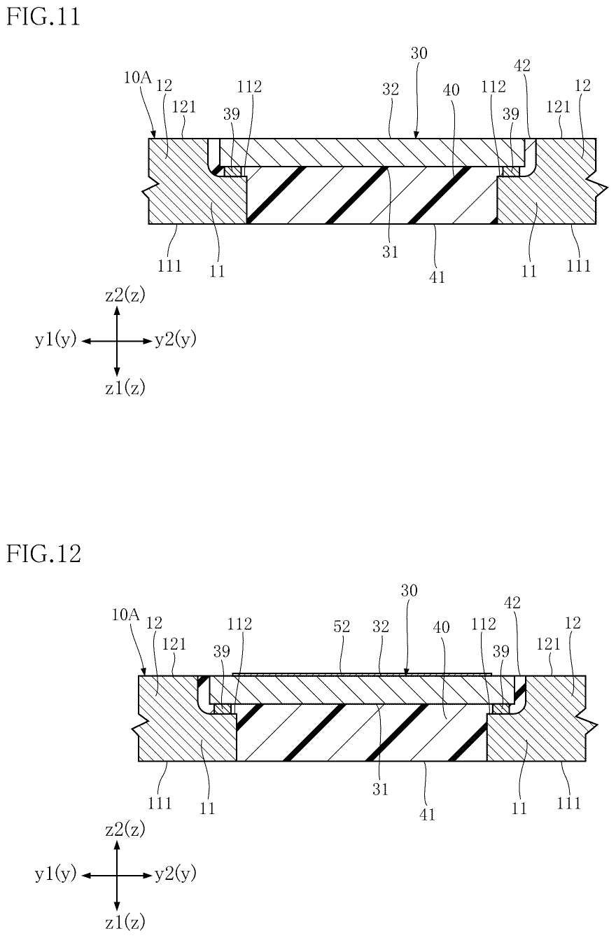

Next, as shown in FIG. 10, a sealing resin 40 is formed to cover the second main surfaces 112 of the wiring portions 11, the terminal portions 12, and the semiconductor element 30. Next, as shown in FIG. 11, the sealing resin 40 is ground from the z2 side in the thickness direction z. Grinding of the sealing resin 40 is performed until it reaches the terminal portions 12 and the semiconductor element 30. As a result, the terminal portions 12 and the semiconductor element are exposed from the sealing resin 40, and the third main surfaces 121, the second element main surface 32, and the second resin main surface 42 are formed. Here, the third main surfaces 121 and the second element main surface 32 are flush with the second resin main surface 42. The surface roughness of the third main surfaces 121, which are formed by grinding, is greater than the surface roughness of the first main surfaces 111, which are not ground. After the terminal portions 12 and the semiconductor element 30 are exposed as shown in FIG. 11, the dimension in the thickness direction z of the wiring portions 11 is equal to or greater than 35% and equal to or less than 150% of the dimension in the thickness direction z of the terminal portions 12.

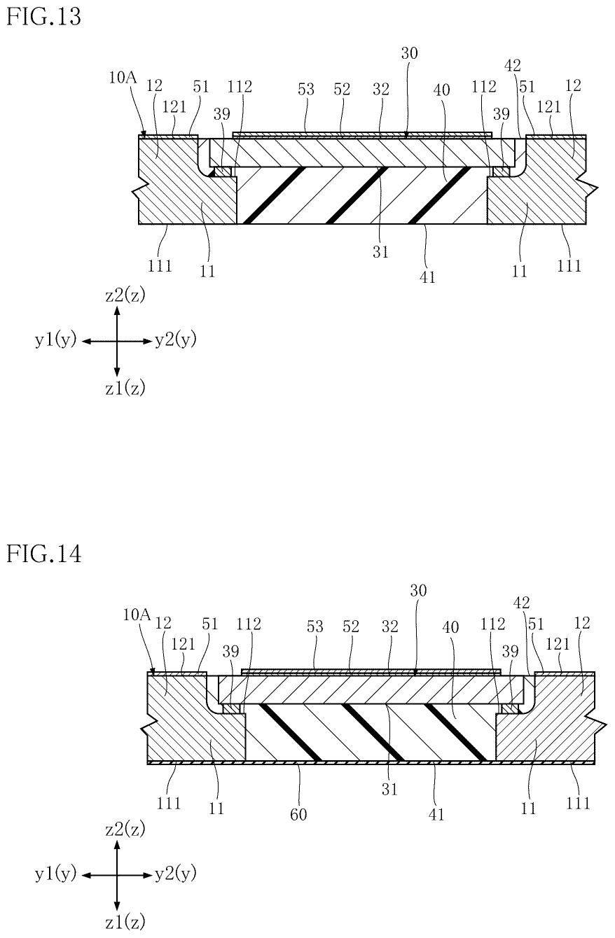

Next, as shown in FIG. 12, a seed layer 52 is formed on the second element main surface 32 of the semiconductor element 30. Specifically, the seed layer 52 is formed by, for example, performing sputtering using a mask to a predetermined area on the second element main surface 32. Next, as shown in FIG. 13, the first metal layers 51 and the second metal layer 53, which are metal plating layers, are collectively formed on the third main surfaces 121 of the terminal portions 12 and the seed layer 52. The first metal layers 51 and the second metal layer 53 are formed, for example, by electroless plating. Next, as shown in FIG. 14, an insulating layer 60 is formed on the first main surfaces 111 of the wiring portion 11 and the first resin main surface 41. The insulating layer 60 covers the entirety of the first main surfaces 111 and the first resin main surface 41.

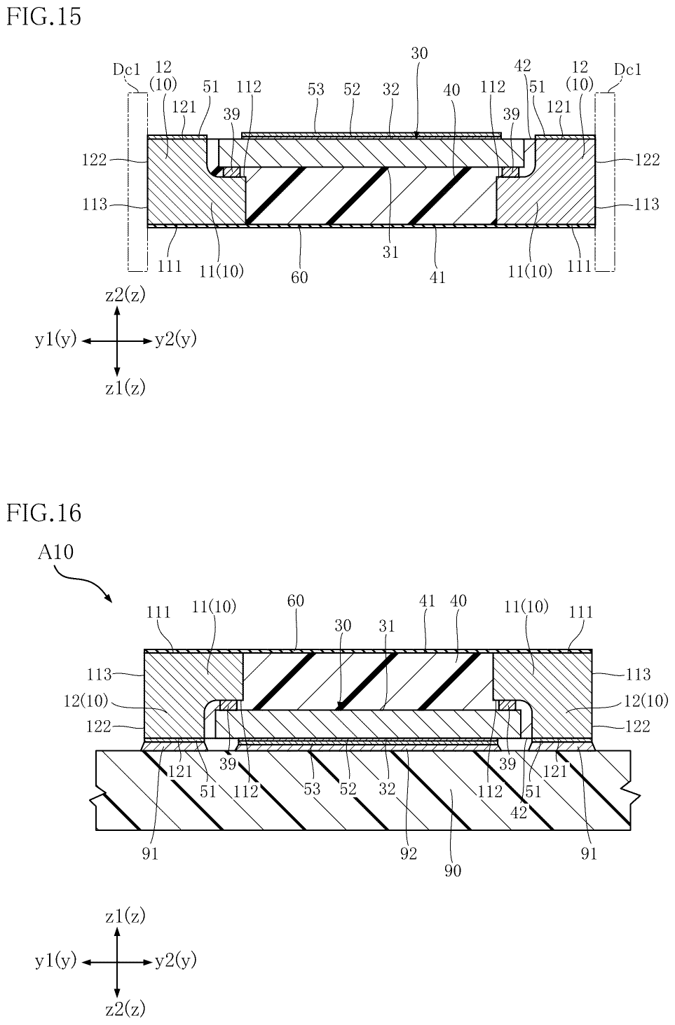

Next, as shown in FIG. 15, the sealing resin 40, the terminal portions 12, and the wiring portions 11 are cut along planes (x-z plane and y-z plane) containing the thickness direction z with a dicer Del, for example. Through these steps, the semiconductor device A10 shown in FIGS. 1 to 7 is obtained.

Next, an example of the use of the semiconductor device A10 will be described based on FIG. 16.

FIG. 16 shows the semiconductor device A10 in use. In this example of use, the semiconductor device A10 is surface-mounted on a circuit board 90. That is, the terminal portions 12 of the conductive members 10 are conductively bonded to the wiring pattern (not shown) of the circuit board 90 via the electrically conductive bonding layers 91. The bonding layers 91 are interposed between the first metal layers 51 and the circuit board 90. Also, the second metal layer 53 formed on the second element main surface 32 (the semiconductor element 30) is bonded to the circuit board 90 via the bonding layer 92. The bonding layers 91 and 92 are, for example, solder.

Next, the effects of the present embodiment will be described.

The semiconductor device A10 includes a plurality of conductive members 10, a semiconductor element 30, and a scaling resin 40. Each conductive member 10 includes a wiring portion 11, and a terminal portion 12 connected to the wiring portion 11 on the z2 side in the thickness direction z. The wiring portion 11 has a first main surface 111 facing the z1 side in the thickness direction z and a second main surface 112 facing the z2 side in the thickness direction z. The terminal portion 12 has a third main surface 121 facing the z2 side in the thickness direction z. The semiconductor element 30 has a first element main surface 31 located on the z2 side in the thickness direction z with respect to the wiring portions 11 and facing the z1 side in the thickness direction z, and a second element main surface 32 facing the z2 side in the thickness direction z. The semiconductor element 30 (the first element main surface 31) is conductively bonded to the second main surfaces 112. The second element main surface 32 is exposed from the sealing resin 40. Each wiring portion 11 has a first side surface 113 facing in a direction orthogonal to the thickness direction z. Each terminal portion 12 has a second side surface 122 facing in a direction orthogonal to the thickness direction z, and the second side surface 122 is connected to the first side surface 113. At least one of the first side surface 113 and the second side surface 122 is exposed from the sealing resin 40. With such a configuration, because the second element main surface 32 of the semiconductor element 30 is exposed from the sealing resin 40, the heat generated in the semiconductor element 30 can be efficiently dissipated to the outside through the second element main surface 32. The heat generated in the semiconductor element 30 can be dissipated to the outside also through the first side surfaces 113 and the second side surfaces 122, which are exposed from the sealing resin 40, of the conductive members 10. In this way, the heat generated in the semiconductor element 30 is efficiently dissipated to the outside directly from the second element main surface 32 of the semiconductor element 30 and also trough the conductive members 10. Thus, the semiconductor device A10 can improve dissipation of the heat generated in the semiconductor element 30.

The scaling resin 40 has a first resin main surface 41 facing the z1 side in the thickness direction z. The first main surfaces 111 of the wiring portions 11 are exposed from the first resin main surface 41. Such a configuration allows the heat generated in the semiconductor element 30 to be dissipated to the outside through the first main surfaces 111, which are exposed from the scaling resin 40, of the conductive members 10. This is favorable for improving the heat dissipation of the semiconductor device A10.

The first dimension L1 in the thickness direction z of the wiring portion 11 is greater than the second dimension L2 in the thickness direction z of the terminal portion 12. Such a configuration can suppress the heat generation in the conductive members 10 (the wiring portions 11), which form the conductive path.

In the semiconductor device A10, the terminal portion 12 of the conductive members 10 surrounds the semiconductor element 30 as viewed in the thickness direction z. The semiconductor element 30 is disposed (on the same side as the terminal portions 12) in the thickness direction z with respect to the wiring portions 11. With such a configuration, each terminal portion 12 overlaps with the semiconductor element 30 as viewed in a direction orthogonal to the thickness direction z, and the dimension in the thickness direction z of the semiconductor device A10 can be reduced. Thus, the volume of the sealing resin 40 can be reduced. This is favorable for improving the heat dissipation of the semiconductor device A10.

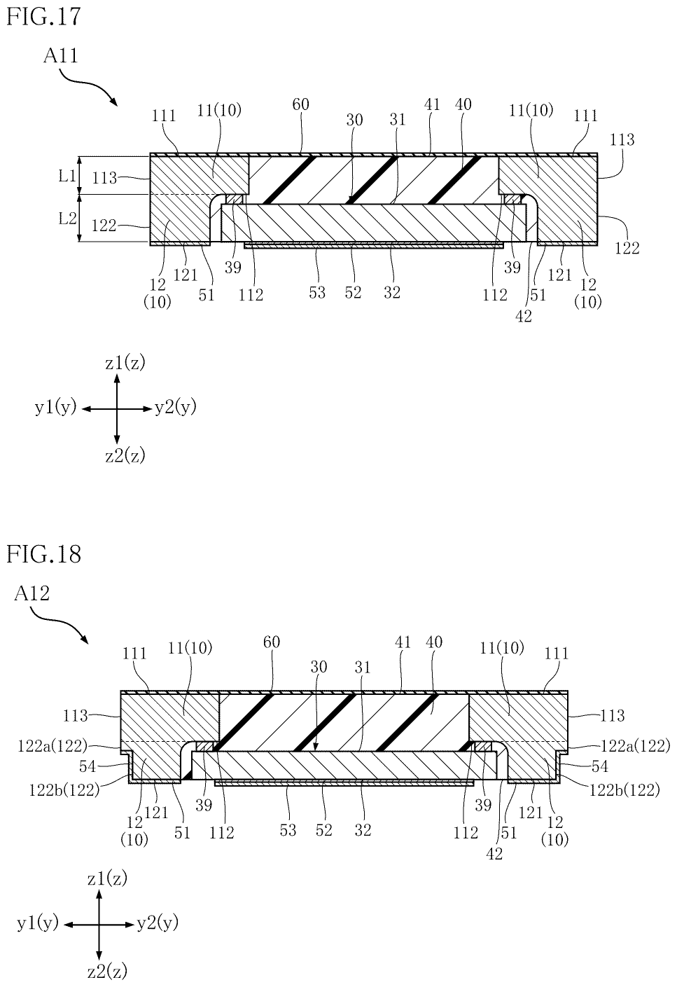

FIGS. 17 to 31 show variations and other embodiments of the semiconductor device of the present disclosure. In these figures, the elements that are identical or similar to those of the above embodiment are denoted by the same reference signs as those of the above embodiment, and the descriptions thereof are omitted. Also, various parts of variations may be selectively used in any appropriate combination as long as it is technically compatible.

### First Variation

FIG. 17 shows a first variation of the semiconductor device A10. FIG. 17 is a sectional view corresponding to FIG. 6, showing a semiconductor device A11 according to the present variation. In the present variation, the relationship between the first dimension L1 in the thickness direction z of the wiring portion 11 and the second dimension L2 in the thickness direction z of the terminal portion 12 differs from that in the semiconductor device A10 of the above embodiment. In the semiconductor device A11, the first dimension L1 in the thickness direction z of the wiring portion 11 is smaller than the second dimension L2 in the thickness direction z of the terminal portion 12.

In the semiconductor device A11 again, because the second element main surface 32 of the semiconductor element 30 is exposed from the sealing resin 40, the heat generated in the semiconductor element 30 can be efficiently dissipated to the outside through the second element main surface 32. The heat generated in the semiconductor element 30 can be dissipated to the outside also through the first side surfaces 113 and the second side surfaces 122, which are exposed from the sealing resin 40, of the conductive members 10. In this way, the heat generated in the semiconductor element 30 is efficiently dissipated to the outside directly from the second element main surface 32 of the semiconductor element 30 and also trough the conductive members 10.

Thus, the semiconductor device A11 can improve dissipation of the heat generated in the semiconductor element 30. Additionally, the semiconductor device A11 has a configuration in common with the semiconductor device A10, thereby achieving the same effect as the semiconductor device A10.

### Second Variation

FIG. 18 shows a second variation of the semiconductor device A10. FIG. 18 is a sectional view corresponding to FIG. 6, showing a semiconductor device A12 according to the present variation. The present variation differs from the semiconductor device A10 of the above embodiment in shape of the terminal portions 12. Also, unlike the semiconductor device A10, the present variation further includes a plating layer 54.

In the semiconductor device A12, the second side surface 122 of each terminal portion 12 has a second outer side surface 122a and a second inner side surface 122b. The second outer side surface 122a is flush with and connected to the first side surface 113 of the wiring portion 11. The second inner side surface 122b is located on the z2 side in the thickness direction z with respect to the second outer side surface 122a. As viewed in the thickness direction z, the second inner side surface 122b is located on the inner side of the sealing resin 40 relative to the second outer side surface 122a. The plating layer 54 is formed on the second inner side surface 122b. The plating layer 54 is not limited to a particular material, but may be, nickel (Ni), palladium (Pd), and gold (Au) plating layers deposited in this order. The plating layer 54 is made of the same material as the first metal layer 51 and connected to the first metal layer 51.

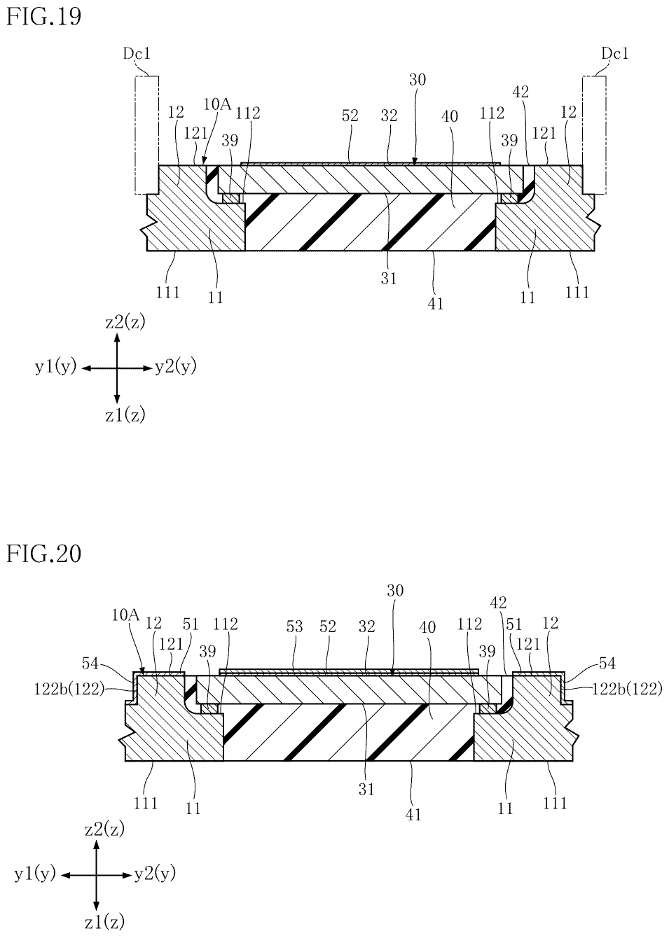

FIGS. 19 to 21 are sectional views corresponding to FIG. 18, each showing a step of the manufacturing method of the semiconductor device A12. In FIGS. 19 to 21, the z1 side and the z2 side in the thickness direction z are inverted.

In the manufacture of the semiconductor device A12, the same steps as those of the method for manufacturing the semiconductor device A10 are performed until the formation of the seed layer 52 is completed. When the formation of the seed layer 52 is completed, the semiconductor device A12 is in the same state as shown in FIG. 12, which shows the manufacturing method of the semiconductor device A10.

In the manufacture of the semiconductor device A12, grooves of a predetermined depth are formed in the sealing resin 40 and the terminal portions 12 from the z2 side in the thickness direction z with a dicer Dc1, as shown in FIG. 19. In this step, the sealing resin 40 and the terminal portions 12 are cut halfway in the thickness direction z. In this way, the second inner side surfaces 122b are formed. On the other hand, the parts on the z1 side in the thickness direction z of the terminal portions 12 and the wiring portions 11 have not been cut.

Next, as shown in FIG. 20, the first metal layers 51, the plating layers 54, and the second metal layer 53, which are metal plating layers, are collectively formed on the third main surfaces 121 of the terminal portions 12, the second inner side surfaces 122b, and the seed layer 52, respectively. The first metal layers 51, the plating layers 54, and the second metal layer 53 are formed, for example, by electroless plating.

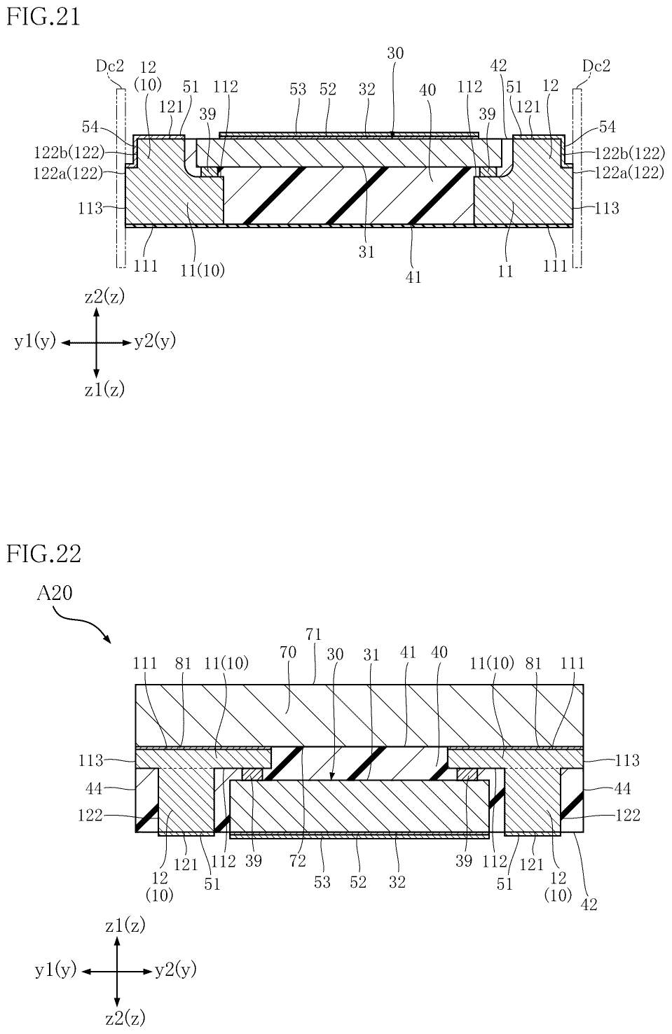

Next, as shown in FIG. 21, the parts on the z1 side in the thickness direction z of the scaling resin 40 and the terminal portions 12, and the wiring portions 11 are cut with a dicer Dc2. In this process, the width of the dicer Dc2 is smaller than that of the dicer Del, so that the plating layers 54 are not cut off. In this way, the semiconductor device A12 is obtained.

In the semiconductor device A12 again, because the second element main surface 32 of the semiconductor element 30 is exposed from the sealing resin 40, the heat generated in the semiconductor element 30 can be efficiently dissipated to the outside through the second element main surface 32. The heat generated in the semiconductor element 30 can be dissipated to the outside also through the first side surfaces 113 and the second side surfaces 122, which are exposed from the sealing resin 40, of the conductive members 10. In this way, the heat generated in the semiconductor element 30 is efficiently dissipated to the outside directly from the second element main surface 32 of the semiconductor element 30 and also trough the conductive members 10. Thus, the semiconductor device A12 can improve dissipation of the heat generated in the semiconductor element 30.

In the semiconductor device A12, the second inner side surfaces 122b of the terminal portions 12 are covered with the plating layers 54. The plating layers 54 have excellent wettability with solder. With such a configuration, for example, when the semiconductor device A12 is bonded to a circuit board using solder, the plating layers 54 are appropriately covered with the solder. This increases the bonding strength of the solder fillet formed on the second inner side surface 122b (the second side surface 122) of each terminal portion 12. In addition, the semiconductor device A12 achieves the same effect as the semiconductor device A10 of the above embodiment.

### Second Embodiment

FIG. 22 shows a semiconductor device A20 according to a second embodiment of the present disclosure. FIG. 22 is a sectional view corresponding to FIG. 6, showing a semiconductor device A20.

The semiconductor device A20 of the present embodiment differs from the above embodiment in configuration of the conductive members 10. Further, the semiconductor device A20 does not include the insulating layer 60. On the other hand, the semiconductor device A20 includes a substrate 70 and seed layers 81.

In the present embodiment, the plurality of conductive members 10 (the wiring portions 11 and the terminal portions 12) are formed by metal plating, for example. The metal material forming the conductive members 10 is, for example, copper (Cu) or a copper alloy.

The wiring portions 11 of the conductive members 10 are located at the same position in the thickness direction z. The wiring portion 11 of each conductive member 10 extends inwardly from the periphery (one of the resin side surfaces 43 and 44) of the sealing resin 40 as viewed in the thickness direction z. The first side surfaces 113 of the wiring portions 11 are exposed from the sealing resin 40 (the resin side surfaces 43 or the resin side surfaces 44).

In the semiconductor device A20, the terminal portion 12 of each conductive member 10 is located slightly more inward than the periphery of the sealing resin 40 is as viewed in the thickness direction z. As viewed in the thickness direction z, the second side surfaces 122 of the terminal portions 12 are located on the inner side of the sealing resin 40 relative to the first side surfaces 113. The second side surfaces 122 are located more inward than the first side surfaces 113 are. The second side surfaces 122 are not connected to the first side surfaces 113 and covered with the sealing resin 40. Unlike the illustrated configuration, the second side surfaces 122 may be connected to the first side surfaces 113 and exposed from the sealing resin 40 in the present embodiment.

The substrate 70 is located on the z1 side in the thickness direction z with respect the conductive members 10 and the sealing resin 40. The substrate 70 has a first substrate main surface 71 and a second substrate main surface 72. The first substrate main surface 71 and the second substrate main surface 72 face away from each other in the thickness direction z. The first substrate main surface 71 faces the z1 side in the thickness direction z. The second substrate main surface 72 faces the z2 side in the thickness direction z. The second substrate main surface 72 is in contact with the first resin main surface 41. The substrate 70 is made of an insulating material or a semiconductor material. In the present embodiment, the substrate 70 is made of a semiconductor material, and the semiconductor material is silicon (Si).

The seed layers 81 are located on the z1 side in the thickness direction z with respect to the first main surfaces 111 of the wiring portions 11. The seed layers 81 are interposed between the first main surfaces 111 and the second substrate main surface 72. The seed layers 81 are in contact with both the first main surfaces 111 and the second substrate main surface 72. The seed layers 81 are thin film layers consisting of, for example, a titanium (Ti) layer and a copper (Cu) layer deposited on top of each other.

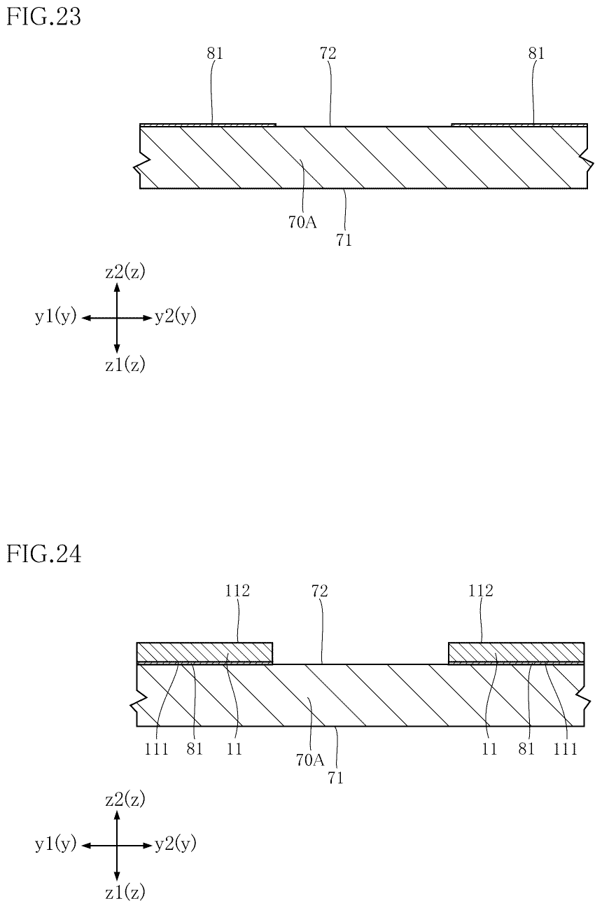

Next, an example of a manufacturing method of the semiconductor device A20 will be described with reference to FIGS. 23 to 31. FIGS. 23 to 31 are sectional views corresponding to FIG. 22, each showing a step of the manufacturing method of the semiconductor device A20. In FIGS. 23 to 31, the z1 side and the z2 side in the thickness direction z are inverted.

First, a base 70A is prepared as shown in FIG. 23. The base 70A is made of a single crystal of a semiconductor material, and is made of Si single crystal in the present embodiment. The base 70A is the component that will later become the substrate 70. Though detailed illustration is omitted, an insulating layer is formed on the surface of the base 70A that faces the z2 side in the thickness direction z (the second substrate main surface 72). The insulating layer is formed by thermally oxidizing the surface of the base 70A that faces the z2 side in the thickness direction z. The base 70A has a size that allows production of a plurality of semiconductor devices A20 described above. That is, the manufacturing steps described below are the steps of a method for manufacturing a plurality of semiconductor devices A20 collectively.

Next, as shown in FIG. 23, seed layers 81 are formed on the surface of the base 70A that faces the z2 side in the thickness direction z (the second substrate main surface 72). Specifically, the seed layers 81 are formed by, for example, performing sputtering using a mask to a predetermined area on the second substrate main surface 72.

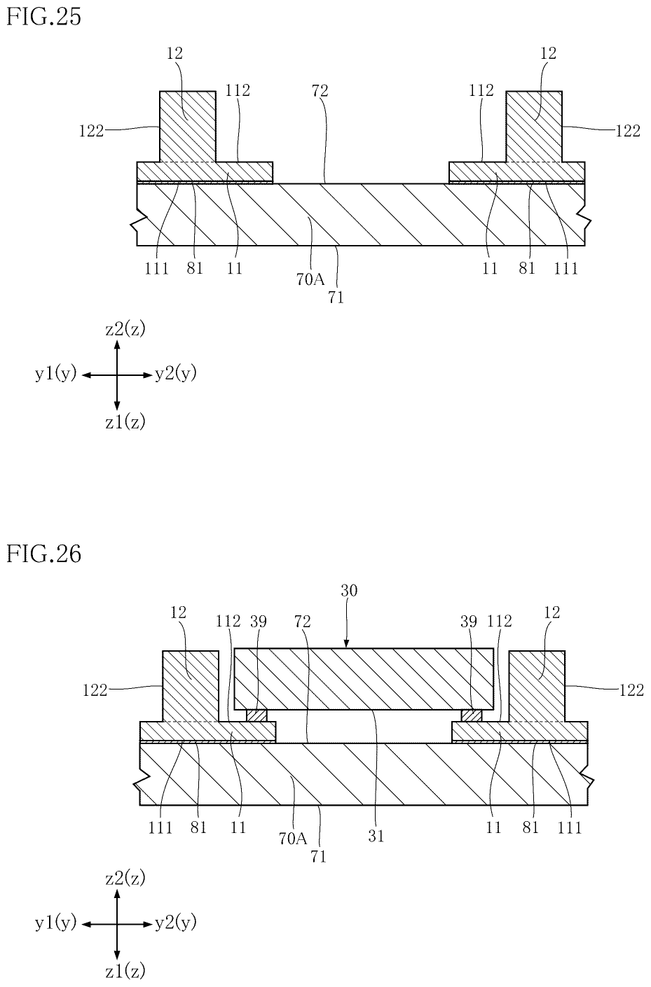

Next, as shown in FIG. 24, wiring portions 11 are formed on the surface of the seed layers 81 that faces the z2 side in the thickness direction z. The wiring portions 11 are formed by depositing the material of the wiring portions 11 on the seed layers 81 by electrolytic plating. Next, as shown in FIG. 25, terminal portions 12 are formed on the surfaces (the second main surfaces 112) of the wiring portions 11 on the z2 side in the thickness direction z. Though detailed illustration is omitted, the formation of the terminal portions 12 is performed by photolithography to form openings and electrolytic plating. Specifically, a resist layer is placed on the surface of the base 70A on the z2 side in the thickness direction z (the second substrate main surface 72) and the surfaces of the wiring portions 11 on the z2 side in the thickness direction z (the second main surfaces 112). Openings are formed in the resist layer at portions corresponding to the terminal portions 12. By forming the openings, a portion of the surface on the z2 side in the thickness direction z of each wiring portion 11 is exposed from the resist layer. Thereafter, the terminal portions 12, which are to join to the wiring portions 11, are formed in the openings through deposition by electrolytic plating.

Next, the semiconductor element 30 is placed on the second main surfaces 112 of the wiring portions 11, as shown in FIG. 26. Specifically, the semiconductor element 30 is placed on the second main surfaces 112 via bonding layers 39. The bonding layers 39 are, for example, solder. By carrying out a heating process (reflow process) after the semiconductor element 30 is placed, the materials of the bonding layers 39 melt, and the semiconductor element 30 and the second main surfaces 112 (the wiring portions 11) are conductively bonded via the bonding layers 39.

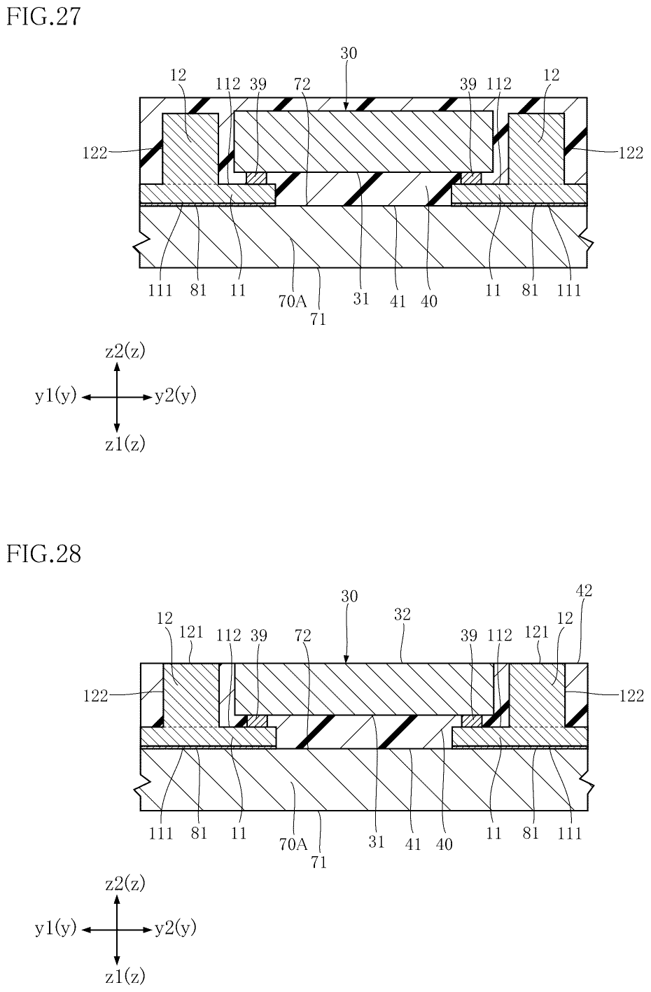

Next, as shown in FIG. 27, a sealing resin 40 is formed to cover the second main surfaces 112 of the wiring portions 11, the terminal portions 12, and the semiconductor element 30. Next, as shown in FIG. 28, the sealing resin 40 is ground from the z2 side in the thickness direction z. Grinding of the sealing resin 40 is performed until it reaches the terminal portions 12 and the semiconductor element 30. As a result, the terminal portions 12 and the semiconductor element are exposed from the sealing resin 40, and the third main surfaces 121, the second element main surface 32, and the second resin main surface 42 are formed. Here, the third main surfaces 121 and the second element main surface 32 are flush with the second resin main surface 42.

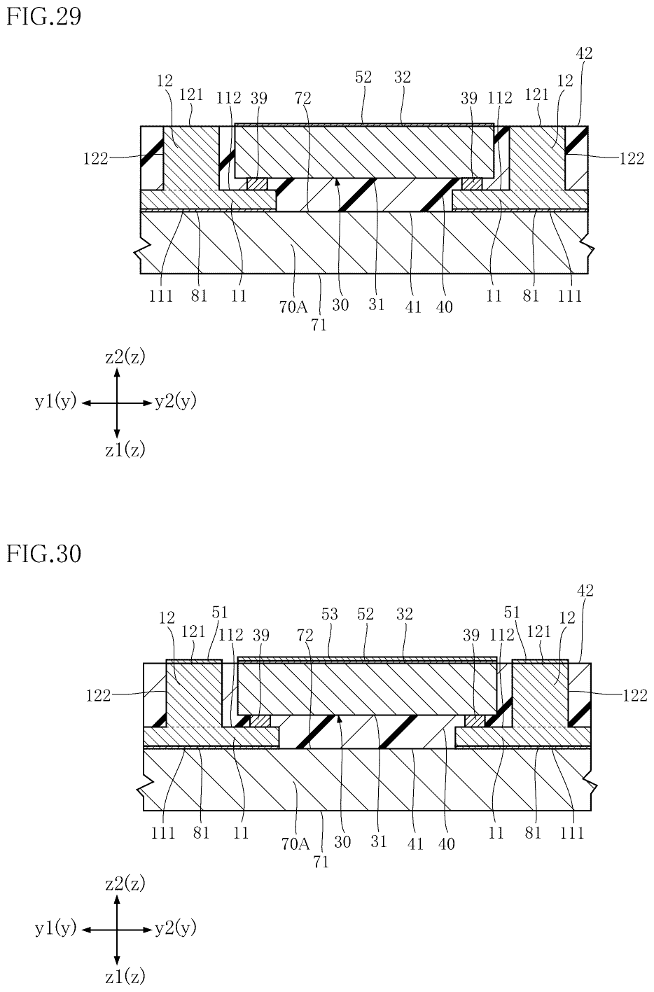

Next, as shown in FIG. 29, a seed layer 52 is formed on the second element main surface 32 of the semiconductor element 30. Specifically, the seed layer 52 is formed by, for example, performing sputtering using a mask to a predetermined area on the second element main surface 32. Next, as shown in FIG. 30, the first metal layers 51 and the second metal layer 53, which are metal plating layers, are collectively formed on the third main surfaces 121 of the terminal portions 12 and the seed layer 52, respectively. The first metal layers 51 and the second metal layer 53 are formed, for example, by electroless plating.

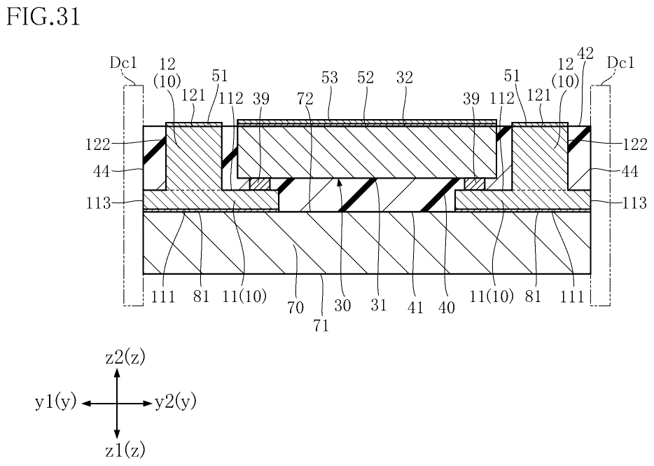

Next, as shown in FIG. 31, the sealing resin 40, the wiring portions 11, and the base 70A are cut along planes (x-z plane and y-z plane) containing the thickness direction z with a dicer Dc1, for example. Through these steps, the semiconductor device A20 shown in FIG. 22 is obtained.

In the semiconductor device A20 again, because the second element main surface 32 of the semiconductor element 30 is exposed from the sealing resin 40, the heat generated in the semiconductor element 30 can be efficiently dissipated to the outside through the second element main surface 32. The heat generated in the semiconductor element 30 can be dissipated to the outside also through the first side surfaces 113, which are exposed from the sealing resin 40, of the conductive members 10. In this way, the heat generated in the semiconductor element 30 is efficiently dissipated to the outside directly from the second element main surface 32 of the semiconductor element 30 and also trough the conductive members 10. Thus, the semiconductor device A20 can improve dissipation of the heat generated in the semiconductor element 30.

The bonding strength of the sealing resin 40 to the conductive members 10 containing copper (Cu) is greater than the bonding strength of the sealing resin 40 to the substrate 70 made of silicon (Si). That is, the sealing resin 40 is less likely to separate at the interface between the conductive members 10 and the sealing resin 40 than at the interface between the substrate 70 and the sealing resin 40. In the present embodiment, the first side surfaces 113 of the wiring portions 11 are exposed from the sealing resin 40, and the sealing resin 40 is in contact with the conductive members 10 (the wiring portions 11) near the first side surfaces 113 of the wiring portions 11. Such a configuration suppresses separation of the sealing resin 40 from the substrate 70. Additionally, the semiconductor device A20 has a configuration in common with the semiconductor device A10, thereby achieving the same effect as the semiconductor device A10.

The semiconductor device according to the present disclosure is not limited to the above-described embodiments. Various modifications in design may be made freely in the specific structure of each part of the semiconductor device according to the present disclosure.

The present disclosure includes configurations related to the following clauses.

### Clause 1.

A semiconductor device comprising:
at least one conductive member including a wiring portion and a terminal portion, the wiring portion including a first main surface facing a first side in a thickness direction and a second main surface facing a second side in the thickness direction, the terminal portion being connected to the wiring portion on the second side in the thickness direction and including a third main surface facing the second side in the thickness direction;
a semiconductor element located on the second side in the thickness direction with respect to the wiring portion and including a first element main surface facing the first side in the thickness direction and a second element main surface facing the second side in the thickness direction; and
a sealing resin covering the semiconductor element and a part of each of the at least one conductive member, wherein
the semiconductor element is bonded to the second main surface,
the wiring portion includes a first side surface facing in a direction orthogonal to the thickness direction,
the terminal portion including a second side surface facing in the direction orthogonal to the thickness direction and connected to the first side surface,
the second element main surface is exposed from the sealing resin, and
at least one of the first side surface and the second side surface is exposed from the sealing resin.

### Clause 2.

The semiconductor device according to clause 1, wherein the sealing resin includes a first resin main surface facing the first side in the thickness direction, and
the first main surface is exposed from the first resin main surface.

### Clause 3.

The semiconductor device according to clause 1 or 2, wherein the semiconductor element is conductively bonded to the second main surface via a bonding layer.

### Clause 4.

The semiconductor device according to any one of clauses 1 to 3, wherein a first dimension in the thickness direction of the wiring portion is equal to or greater than 35% and equal to or less than 150% of a second dimension in the thickness direction of the terminal portion.

### Clause 5.

The semiconductor device according to clause 4, wherein the first dimension is greater than the second dimension.

### Clause 6.

The semiconductor device according to any one of clauses 1 to 5, wherein the at least one conductive member comprises a plurality of conductive members, and
the terminal portions of the plurality of conductive members surround the semiconductor element as viewed in the thickness direction.

### Clause 7.

The semiconductor device according to any one of clauses 1 to 6, wherein the sealing resin includes a second resin main surface facing the second side in the thickness direction, and
the third main surface and the second element main surface are flush with the second resin main surface.

### Clause 8.

The semiconductor device according to any one of clauses 1 to 7, further comprising a first metal layer located on the second side in the thickness direction of the third main surface and in contact with the third main surface.

### Clause 9.

The semiconductor device according to clause 8, further comprising a second metal layer located on the second side in the thickness direction of the second element main surface.

### Clause 10.

The semiconductor device according to clause 9, wherein the first metal layer and the second metal layer are made of a same material.

### Clause 11.

The semiconductor device according to clause 9 or 10, further comprising a seed layer interposed between the second element main surface and the second metal layer.

### Clause 12.

The semiconductor device according to any one of clauses 1 to 11, wherein the at least one conductive member is formed from a lead frame.

### Clause 13.

The semiconductor device according to any one of clauses 1 to 12, wherein the sealing resin includes a resin side surface facing in a direction orthogonal to the thickness direction, and
the first side surface is exposed from the resin side surface and flush with the resin side surface.

### Clause 14.

The semiconductor device according to clause 13, wherein the second side surface includes a second outer side surface connected to and flush with the first side surface, and a second inner side surface located on the second side in the thickness direction with respect to the second outer side surface and located on an inner side of the sealing resin relative to the second outer side surface, and
the semiconductor device further includes a plating layer formed on the second inner side surface.

### Clause 15.

The semiconductor device according to any one of clauses 1 to 14, wherein surface roughness of the third main surface is greater than surface roughness of the first main surface.

### Clause 16.

The semiconductor device according to any one of clauses 1 to 15, further comprising an insulating layer located on the first side in the thickness direction of the first main surface and in contact with the first main surface.

### Clause 17.

A method for manufacturing a semiconductor device, the method comprising the steps of:
preparing a conductive member formed from a lead frame and including a wiring portion and a terminal portion, the wiring portion including a first main surface facing a first side in a thickness direction and a second main surface facing a second side in the thickness direction, the terminal portion being connected to the wiring portion on the second side in the thickness direction;
placing a semiconductor element on the second main surface;
forming a sealing resin to cover the second main surface, the terminal portion, and the semiconductor element;
exposing the terminal portion and the semiconductor element by grinding the sealing resin from the second side in the thickness direction; and
cutting the sealing resin, the terminal portion, and the wiring portion along a plane containing the thickness direction.

### Clause 18.

The method for manufacturing a semiconductor device according to clause 17, further comprising the step of forming a seed layer on the semiconductor element after the step of exposing the terminal portion and the semiconductor element.

### Clause 19.

The method for manufacturing a semiconductor device according to clause 18, further comprising the step of collectively forming a metal plating layer on the terminal portion and the seed layer after the step of forming a seed layer on the semiconductor element.

### Clause 20.

The method for manufacturing a semiconductor device according to any one of clauses 17 to 19, wherein a dimension in the thickness direction of the wiring portion is equal to or greater than 35% and equal to or less than 150% of a dimension in the thickness direction of the terminal portion after the step of exposing the terminal portion and the semiconductor element.

### REFERENCE NUMERALS

| | |
|---|---|
| A10, A11, A12, A20: | |
| Semiconductor device | |
| 10, 10A: Conductive member | 11: Wiring portion |
| 111: First main surface | 112: Second main surface |
| 113: First side surface | 12: Terminal portion |
| 121: Third main surface | 122: Second side surface |
| 122a: Second outer side surface | |
| 122b: Second inner side surface | |
| 30: Semiconductor element | 31: First element main surface |
| 32: Second element main surface | 39: Bonding layer |
| 40: Sealing resin | 41: First resin main surface |
| 42: Second resin main surface | 43, 44: Resin side surface |
| 51: First metal layer | 52: Seed layer |
| 53: Second metal layer | 54: Plating layer |
| 60: Insulating layer | 70: Substrate |
| 70A: Base | 71: First substrate |
| | main surface |
| 72: Second substrate main surface | 90: Circuit board |
| 91, 92: Bonding layer | Dc1, Dc2: Dicer |
| L1: First dimension | L2: Second dimension |
| L3: Dimension | x: First direction |
| y: Second direction | z: Thickness direction |

1. A semiconductor device comprising:
at least one conductive member including a wiring portion and a terminal portion, the wiring portion including a first main surface facing a first side in a thickness direction and a second main surface facing a second side in the thickness direction, the terminal portion being connected to the wiring portion on the second side in the thickness direction and including a third main surface facing the second side in the thickness direction;
a semiconductor element located on the second side in the thickness direction with respect to the wiring portion and including a first element main surface facing the first side in the thickness direction and a second element main surface facing the second side in the thickness direction; and
a sealing resin covering the semiconductor element and a part of each of the at least one conductive member, wherein
the semiconductor element is bonded to the second main surface,
the wiring portion includes a first side surface facing in a direction orthogonal to the thickness direction,
the terminal portion including a second side surface facing in the direction orthogonal to the thickness direction and connected to the first side surface,
the second element main surface is exposed from the sealing resin, and
at least one of the first side surface and the second side surface is exposed from the sealing resin.

2. The semiconductor device according to claim 1, wherein the sealing resin includes a first resin main surface facing the first side in the thickness direction, and
the first main surface is exposed from the first resin main surface.

3. The semiconductor device according to claim 1, wherein the semiconductor element is conductively bonded to the second main surface via a bonding layer.

4. The semiconductor device according to claim 1, wherein a first dimension in the thickness direction of the wiring portion is equal to or greater than 35% and equal to or less than 150% of a second dimension in the thickness direction of the terminal portion.

5. The semiconductor device according to claim 4, wherein the first dimension is greater than the second dimension.

6. The semiconductor device according to claim 1, wherein the at least one conductive member comprises a plurality of conductive members, and
the terminal portions of the plurality of conductive members surround the semiconductor element as viewed in the thickness direction.

7. The semiconductor device according to claim 1, wherein the sealing resin includes a second resin main surface facing the second side in the thickness direction, and
the third main surface and the second element main surface are flush with the second resin main surface.

8. The semiconductor device according to claim 1, further comprising a first metal layer located on the second side in the thickness direction of the third main surface and in contact with the third main surface.

9. The semiconductor device according to claim 8, further comprising a second metal layer located on the second side in the thickness direction of the second element main surface.

10. The semiconductor device according to claim 9, wherein the first metal layer and the second metal layer are made of a same material.

11. The semiconductor device according to claim 10, further comprising a seed layer interposed between the second element main surface and the second metal layer.

12. The semiconductor device according to claim 1, wherein the at least one conductive member is formed from a lead frame.

13. The semiconductor device according to claim 1, wherein the sealing resin includes a resin side surface facing in a direction orthogonal to the thickness direction, and
the first side surface is exposed from the resin side surface and flush with the resin side surface.

14. The semiconductor device according to claim 13, wherein the second side surface includes a second outer side surface connected to and flush with the first side surface, and a second inner side surface located on the second side in the thickness direction with respect to the second outer side surface and located on an inner side of the sealing resin relative to the second outer side surface, and
the semiconductor device further includes a plating layer formed on the second inner side surface.

15. The semiconductor device according to claim 1, wherein surface roughness of the third main surface is greater than surface roughness of the first main surface.

16. The semiconductor device according to claim 1, further comprising an insulating layer located on the first side in the thickness direction of the first main surface and in contact with the first main surface.

17. A method for manufacturing a semiconductor device, the method comprising the steps of:
preparing a conductive member formed from a lead frame and including a wiring portion and a terminal portion, the wiring portion including a first main surface facing a first side in a thickness direction and a second main surface facing a second side in the thickness direction, the terminal portion being connected to the wiring portion on the second side in the thickness direction;
placing a semiconductor element on the second main surface;
forming a sealing resin to cover the second main surface, the terminal portion, and the semiconductor element;
exposing the terminal portion and the semiconductor element by grinding the sealing resin from the second side in the thickness direction; and
cutting the sealing resin, the terminal portion, and the wiring portion along a plane containing the thickness direction.

18. The method for manufacturing a semiconductor device according to claim 17, further comprising the step of forming a seed layer on the semiconductor element after the step of exposing the terminal portion and the semiconductor element.

19. The method for manufacturing a semiconductor device according to claim 18, further comprising the step of collectively forming a metal plating layer on the terminal portion and the seed layer after the step of forming a seed layer on the semiconductor element.

20. The method for manufacturing a semiconductor device according to any one of claim 17, wherein a dimension in the thickness direction of the wiring portion is equal to or greater than 35% and equal to or less than 150% of a dimension in the thickness direction of the terminal portion after the step of exposing the terminal portion and the semiconductor element.
